(19) United States
(12) Patent Application Publication
(10) Pub. No.: US 2008/0217687 A1
(43) Pub. Date: Sep. 11, 2008

(54) Active device array substrate and repairing method thereof

(75) Inventor: Yuan-Hsin Tsou, Padeh City (TW)

Correspondence Address: Joe McKinney Muncy, PO Box 1364, Fairfax, VA, 22038-1364, US

(73) Assignee: CHUNGHWA PICTURE TUBES, LTD

(21) Appl. No.: 11/896,095

(22) Filed: Aug. 29, 2007

(30) Foreign Application Priority Data
Mar. 9, 2007 (TW) 96108123

(51) Int. Cl. H01L 29/786; H01L 21/00

(52) U.S. Cl. 257/347; 438/4; 257/E29.273; 257/E21.001

(57) ABSTRACT

A simple active device array substrate and an easy repairing method thereof are provided. The pattern layer of the drain electrode has an extended portion extending to the region between an adjacent pixel electrode and the substrate. Once the pixel is found to be a white defect, a laser beam is used to irradiate the overlapped region of the extended portion of the pattern layer of the drain electrode and the adjacent pixel electrode. Then, the current pixel will have the same brightness and color with the adjacent pixel, such that the repairing purpose is achieved.

### BACKGROUND OF THE INVENTION

1. Field of the Invention

The present invention relates to an active device array substrate, and more particularly, to a pixel structure of the active device array substrate and the repairing method thereof.

2. Description of the Prior Art

The Thin Film Transistor-Liquid Crystal Display (TFT-LCD) is the most popular Flat Panel Display (FPD) recently because of its many benefits, such as its low power consumption, thin shape, light weight, and low driving voltage, etc.

In recent years, the TFT-LCD has been developed towards to the application field of television, so as the display panel has also been developed towards to the large-scale design. Consequently, the fabrication process is becoming more and more complex and difficult because of the large-scale design. In the influence of the display quality of the panel, it is hard to give consideration to both the constraint conditions and the process errors at the same time.

Generally, the liquid crystal of the TFT-LCD is filled between an active device array substrate with electrodes thereon and a color filter (CF) substrate with electrodes thereon. The image display region of the active device array substrate contains a plurality of pixels configured in arrays. A pixel is defined as the enclosed region intersected by two adjacent scan lines and two adjacent data lines.

During the procedures of fabricating the active device array substrate, the static electricity and the unexpected particle pollution are easily occurring to result in an abnormal short-circuit or open-circuit of a TFT of the substrate

The pixel defects can be distinguished as several kinds such as the white defect, the black defect, and the gray defect, etc. For example, the white defect is bright even on a black picture, so the human's eyes are very sensitive to it and easy to recognize. Therefore, a laser repairing process will be executed conventionally as a few white defects occurring.

A partial top-view schematic diagram of a pixel with the conventional laser repairing structure in the active device array substrate is illustrated in FIG. 1. A Data line 114 transmits a data signal to a pattern layer of the source electrode 100. A scan signal is transmitted by a scan line 104. In the pixel, a storage capacitance line 110 is provided to transmit the common voltage. Wherein, scan line 104 and storage capacitance line 110 are located in the first metal layer on a substrate, and data line 114 is located in another metal layer on the substrate. The channel layer 102 is partially covered by the pattern layer of the source electrode 100 and partially covered by the drain electrode 106. A contact hole 108 is used to electrically connect the pixel electrode 112 and the drain electrode 106.

Once the pixel is found to be a white defect, the laser beam can be used to irradiate the region 119 to electrically connect the drain electrode 106 and the scan line 104. The region 119 is arbitrarily selected within the overlapped region 118 of the drain electrode 106 and the scan line 104. Then, the scan signal can be transmitted to the pixel electrode 112 through the drain electrode 106 to convert the white defect into a black defect and so as to achieve the repairing purpose.

Therefore, this kind of pixel structure and laser repairing method for repairing a white defect eliminates the drawback of being always bright for a pixel. However, it will make the pixel always dark even the data signal exists. And the display quality of TFT-LCD will be lower down because the pixel can not display any brightness or color.

FIG. 2 is another partial top-view schematic diagram of a pixel with the conventional laser repairing structure in the active device array substrate. A Data line 214 transmits a data signal to the pattern layer of the source electrode 200. The scan signal is transmitted by the scan line 204. In the pixel, a storage capacitance line 210 is provided to transmit a common voltage. Wherein, a scan line 204 and the storage capacitance line 210 are located in the first metal layer on a substrate, and the data line 214 is located in another metal layer on the substrate. The channel layer 202 is partially covered by the pattern layer of the source electrode 200 and partially covered by the drain electrode 206. A contact hole 208 is to electrically connect the pixel electrode 212 and the drain electrode 206. One floating metal conductor 216 located in the first metal layer is prepared for the laser repairing in necessity. The floating metal conductor 216 is partially overlapped with the data line 214 and the drain electrode 206 respectively at the overlapped regions 218 and 220.

Once the pixel is found to be a white defect, two laser beams can be used to irradiate the regions 219 and 221 from the lower surface side of the substrate to electrically connect the data line 214 and the floating metal conductor 216, and electrically connect the drain electrode 206 and the floating metal conductor 216. The regions 219 and 221 are arbitrarily selected within the overlapped regions 218 and 220. Then, the data line 214 can be electrically connected with the drain electrode 206 through the floating metal conductor 216. Thus, the data signal can be directly transmitted to the pixel electrode 212 through the contact hole 208 to convert the white defect into a gray defect and so as to achieve the repairing purpose.

Therefore, this kind of pixel structure and laser repairing method for repairing a white defect is free of the drawback of being always bright or always dark for a pixel. However, it will make the pixel flicker when the positive-negative polarity of the data signal is alternating, and so as to degrade the display quality of the TFT-LCD panel.

In addition, this kind of pixel structure and laser repairing method for repairing a white defect needs a floating metal conductor located in the first metal layer under the pixel electrode. Thus, the floating metal conductor will decrease the aperture ratio of the pixel. Furthermore, this kind of pixel structure and laser repairing method needs to irradiate two laser beams. Hence, it will increase the repairing time and cost.

### SUMMARY OF THE INVENTION

One object of the present invention is to provide a simple active device array substrate and an easy repairing method thereof. The pattern layer of the drain electrode has an extended portion extending to the region between the adjacent pixel electrode and the substrate, so the white defect will have the same brightness and color with the adjacent pixel after the laser irradiation.

Another object of the present invention is to make the pattern of the first metal layer and the pattern of the second metal layer have an allowable error range of a relative displacement, whereby the overlapped area between the pattern layer of the drain electrode and the scan line is a constant in the allowable error range of the relative displacement. Thus, the charge-discharge time of the pixel electrode is also a constant. Consequently, the brightness and display quality of the whole picture may maintain even and fine.

Another object of the present invention is to provide a laser repairing region, such that the repairing position is easy to be recognized and the uniformity and strength of the laser fusion can be assured.

To achieve the objects mentioned above, one embodiment of the present invention is to provide an active device array substrate, which comprises: a substrate; and a plurality of pixel structures configured in arrays on the substrate, wherein a plurality of scan lines and a plurality of data line are defined the pixel structures, each of the pixel structures comprises: an active device configured on the substrate, wherein the active device comprises: a pattern layer of a gate electrode configured on the substrate and electrically connecting with the corresponding scan line; a gate insulation layer covering the pattern layer of the gate electrode and the substrate; a channel layer configured on the gate insulation layer which is over the pattern layer of the gate electrode; a pattern layer of a source electrode and a pattern layer of a drain electrode respectively configured on two sides of the channel layer, wherein the source electrode is electrically connecting with the corresponding data line, and the pattern layer of the drain electrode has a first extended portion; and a passivation layer covering the active device; and a pixel electrode configured on the passivation layer and electrically connecting with the pattern layer of the drain electrode, wherein the first extended portion of the pattern layer of the drain electrode is extended to the region between an adjacent pixel electrode and the substrate.

To achieve the objects mentioned above, another embodiment of the present invention is to provide a repairing method applied for an active device array substrate, which comprises: providing the active device array substrate; and electrically connecting the first extended portion of the pattern layer of the drain electrode with the adjacent pixel electrode.

### BRIEF DESCRIPTION OF THE DRAWINGS

The foregoing aspects and many of the accompanying advantages of this invention will become more readily appreciated as the same becomes better understood by reference to the following detailed description,

FIG. 1 is a partial top-view schematic diagram of a pixel with the conventional laser repairing structure in an active device array substrate for a first prior art;

FIG. 2 is a partial top-view schematic diagram of a pixel with the conventional laser repairing structure in an active device array substrate for a second prior art;

FIG. 3A is a top-view schematic diagram of partial pixels with the laser repairing structure in an active device array substrate according to a first embodiment of the present invention;

FIG. 3B is an amplified schematic diagram of the partial pixels “P” in FIG. 3A;

FIG. 3C is a cross-sectional schematic diagram taken from the cross-segment “A-A′” in FIG. 3B;

FIG. 3D is a cross-sectional schematic diagram taken from the cross-segment “B-B′” in FIG. 3B

FIG. 3E is a cross-sectional schematic diagram taken from the cross-segment “C-C′” in FIG. 3B;

FIG. 4A is a top-view schematic diagram of the partial pixels with the laser repairing structure in an active device array substrate according to a second embodiment of the present invention;

FIG. 4B is a top-view schematic diagram after the pattern of the second metal layer in FIG. 4A has displaced an “X” distance to the right relative to the pattern of the first metal layer; and

FIG. 5 is a top-view schematic diagram of the partial pixels with the laser repairing structure in an active device array substrate according to a third embodiment of the present invention.

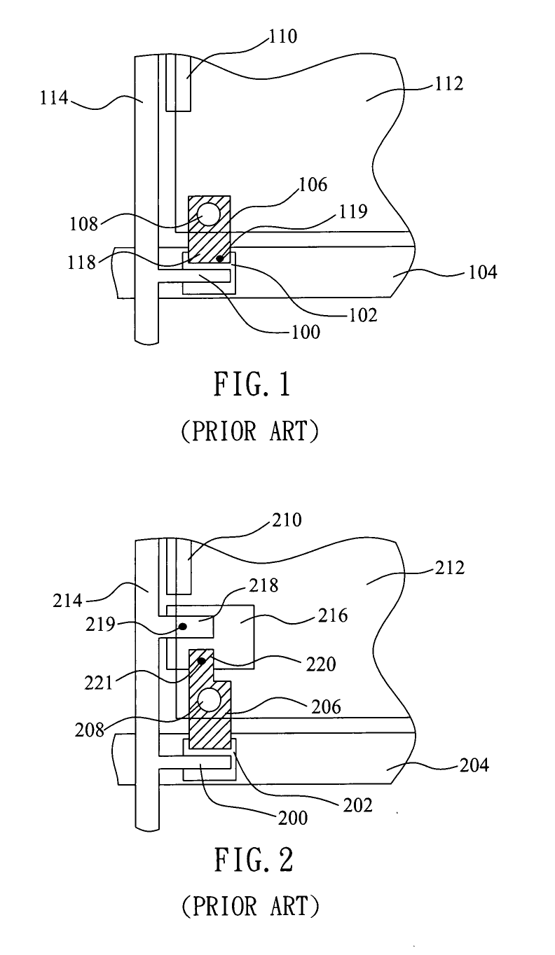

### DESCRIPTION OF THE PREFERRED EMBODIMENT

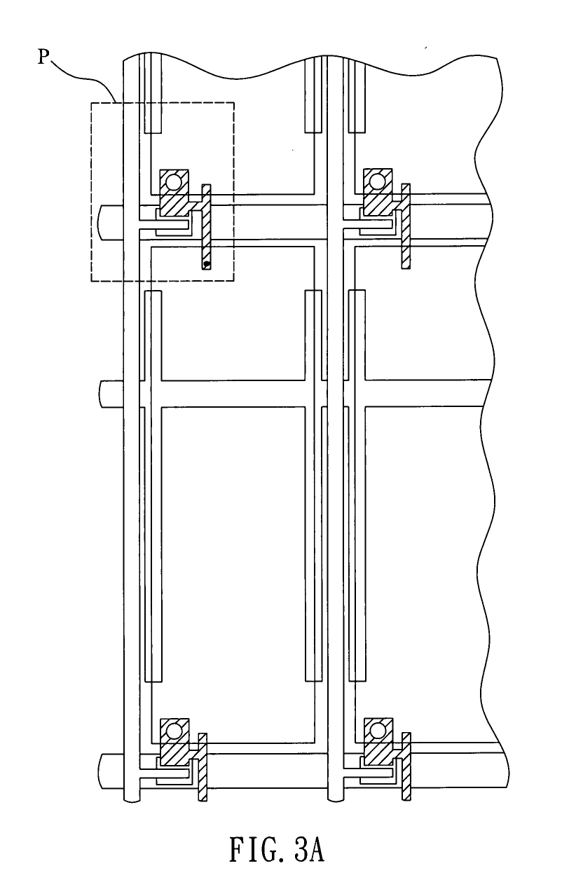

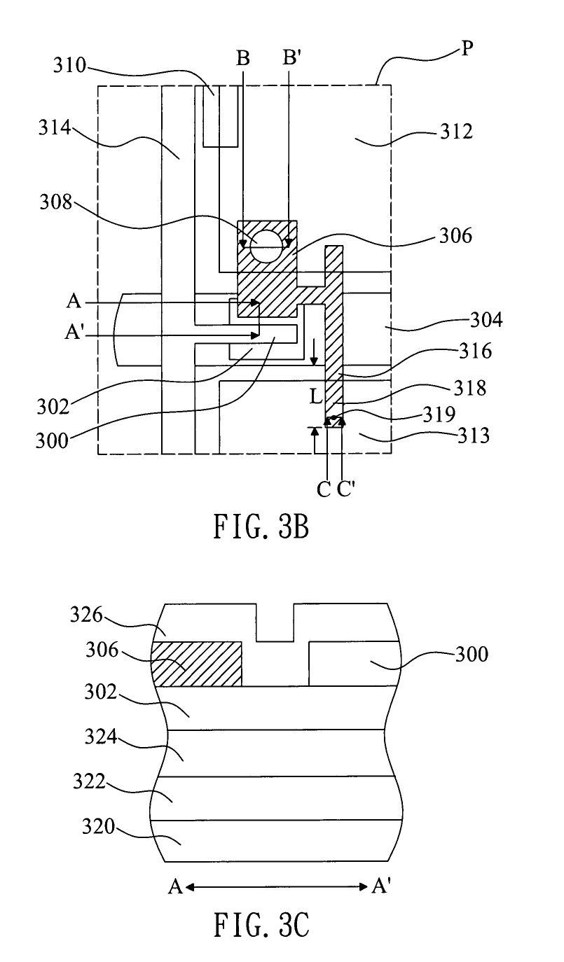

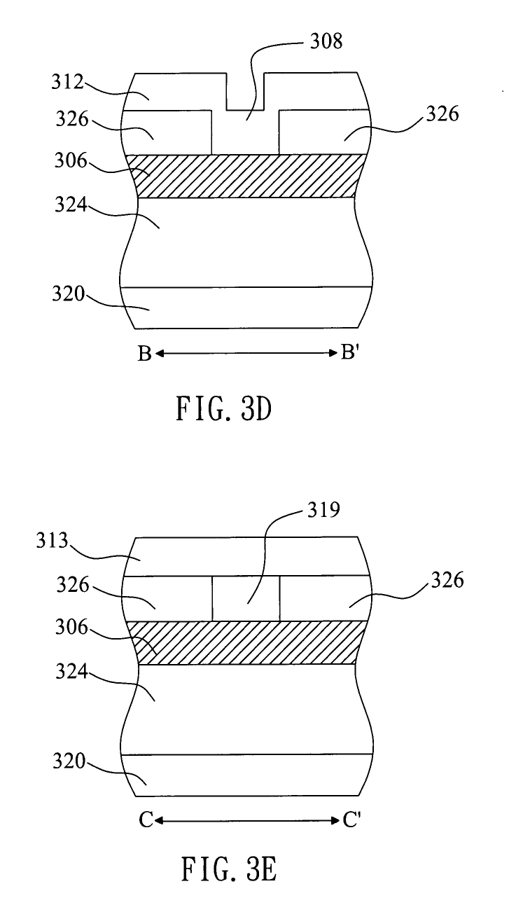

FIG. 3A is a top-view schematic diagram of partial pixels with the laser repairing structures in an active device array substrate according to a first embodiment of the present invention. The active device array substrate comprises a plurality of pixel structures configured in arrays on the substrate.

FIG. 3B is an amplified schematic diagram of the partial pixels “P” in FIG. 3A. Each of pixel structures includes an active device and a pixel electrode 312. The active device includes at least two metal layers. The first metal layer includes a scan line 304, a storage capacitance line 310 and a pattern layer of a gate electrode (not shown in the figure). The scan line 304 has a portion of gate electrode (not shown in the figure) located under a channel layer 302, the scan signal is transmitted to the gate electrode by the scan line 304. The scan line 304 extends in a row direction. The storage capacitance line 310 is to transmit a common voltage. The second metal layer includes a data line 314, a pattern layer of a source electrode 300 and a pattern layer of a drain electrode 306. The data line 314 transmits the data signal to the pattern layer of the source electrode 300, wherein the pattern layer of the source electrode 300 and the pattern layer of the drain electrode 306 are respectively configured on two sides of the channel layer 302. A contact hole 308 is used to electrically connect the pixel electrode 312 with the pattern layer of the drain electrode 306. The drain electrode 306 has a first extended portion 316 extending to the region between an adjacent pixel electrode 313 and the substrate, wherein the overlapped region 318 of the first extended portion 316 and the pixel electrode 313 is configured for laser repairing.

There is no special limitation of the shape and the length “L” of the first extended portion 316, which the shape of the first extended portion 316 is a rectangle in this embodiment. The requirement of the length “L” should be long enough to do the laser fusion, and it is equal or smaller than 15 micrometers in one preferred embodiment. And furthermore, owing to the length “L” is so short, it is very easy to design the black matrix (BM) (not shown in the figure) of the CF substrate to make the first extended portion 316 be shielded by the BM after the active device array substrate and the CF substrate are assembled to a complete display panel. Therefore, the aperture ratio and display quality will not be affected by the first extended portion 316.

Generally, the material of the first metal layer and the second metal layer includes Al, Cu, Au, Cr, Ta, Ti, Mo, Ni, Ag or their combinations. And the conductive pixel electrodes 312, 313 are indium tin oxide (ITO) or indium zinc oxide (IZO).

FIG. 3C is a cross-sectional schematic diagram taken from the cross-segment “A-A′” in FIG. 3B. A gate electrode 322 is intervened between a substrate 320 and a gate insulation layer 324. The material of the substrate 320 is transparent glass in one preferred embodiment. The gate electrode 322 is one part of the scan line 304 in FIG. 3B. The channel layer 302 is configured on the gate insulation layer 324. The pattern layer of the drain electrode 306 and the pattern layer of the source electrode 300 are spaced out and electrically insulated by a passivation layer 326. In one preferred embodiment, the gate insulation layer 324 and the passivation layer 326 are oxide or nitride.

FIG. 3D is a cross-sectional schematic diagram taken from the cross-segment “B-B′” in FIG. 3B. A contact hole 308 is to electrically connect the pixel electrode 312 with the pattern layer of the drain electrode 306.

Once the pixel is found to be a white defect, a laser beam may be used to irradiate a region 319, which is arbitrarily selected within the overlapped region 318. FIG. 3E is a cross-sectional schematic diagram taken from the cross-segment “C-C′” in FIG. 3B to illustrate the cross-sectional structure of the region 319 after being irradiated by the laser beam. The pattern layer of the drain electrode 306 and the pixel electrode 313 of the adjacent pixel are electrically connected through the molten region 319. Referring to FIG. 3B and FIG. 3E together, the region 319 of the active device array substrate can be irradiated by the laser beam from the lower surface of the substrate 320 or from the upper surface of the pixel electrode 313 of the adjacent pixel. Thus, the pixel signal of the adjacent pixel can be transmitted to the pixel electrode 312 through the region 319 and the contact hole 308. Consequently, the current pixel will have the same brightness and color with the adjacent pixel, such that the repairing purpose is achieved.

One feature of this embodiment is that it just needs to do the laser irradiation once for repairing the white defect. Because the overlapped region 318 is extended from the pattern layer of the drain electrode 306, another feature of this embodiment of the structure and method for repairing the white defect is without additional photo-mask or fabrication process to practice the present invention.

In addition, the pixel structure of the active device array substrate of the present invention can be further designed. The pattern of the first metal layer and the pattern of the second metal layer have an allowable error range of a relative displacement. In the error range of the relative displacement, the parasitic capacitance of gate electrode and drain electrode (C_{gd}) is a constant so as the brightness and display quality of the whole picture may maintain even and fine. The detailed explanation and embodiments are described in the following.

As described previously, the active device array substrate comprises at least two metal layers. The first metal layer includes a scan line, a pattern layer of a gate electrode and a storage capacitance line. The second metal layer includes a data line, a pattern layer of a source electrode and a pattern layer of a drain electrode. There exists a C_{gd} between the pattern layer of the drain electrode and the scan line with the pattern layer of the gate electrode. The C_{gd} is proportional to their overlapped area, and the charge-discharge time of the pixel electrode is proportional to the C_{gd}.

Because the process error can not be completely avoided, it may exist a relative displacement error between the pattern of the first metal layer and the pattern of the second metal layer in the partial or whole display picture. Then, the change of the C_{gd} and the charge-discharge time of the pixel electrode will induce a phenomenon of the uneven brightness or bad display quality in the partial or whole display picture.

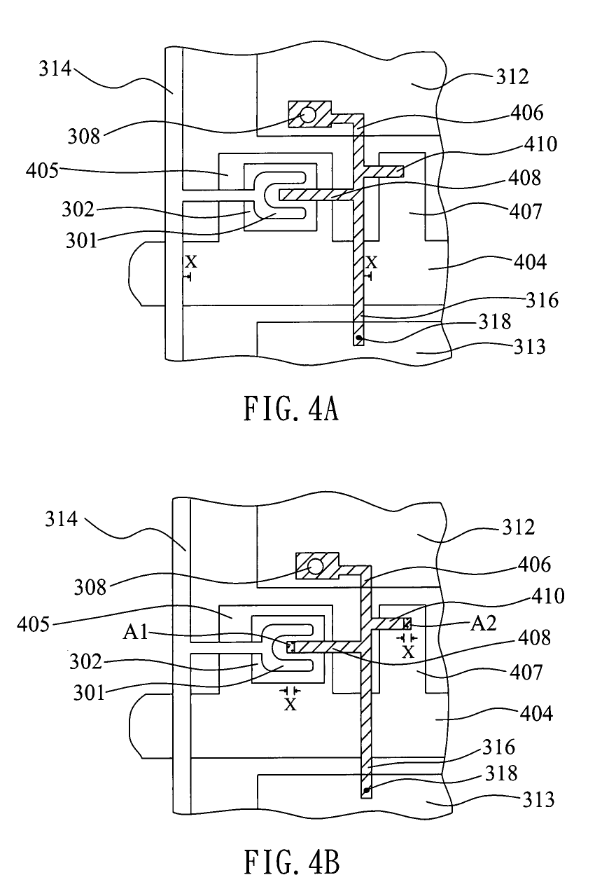

Nevertheless, the pixel structure and repairing method of the present invention to repairing a white defect by changing it to have the same brightness and color of the adjacent pixel is suitable for many different kinds of pixel structure design for the active device array substrate. The second embodiment of the present invention is illustrated in FIG. 4A. The scan line 404 has an extended pattern layer of a gate electrode 405 and a protrusion 407. The gate electrode (not shown in the figure) is included in the extended pattern layer of the gate electrode 405. The pattern layer of the source electrode 301 has a curved concavity and is extended from the data line 314. The second extended portion 408 of the pattern layer of the drain electrode 406 is extended into the curved concavity of the pattern layer of the source electrode 301. The third extended portion 410 of the pattern layer of the drain electrode 406 is extending to a upper side over the protrusion 407 of the scan line 404.

In this embodiment, the pattern of the first metal layer and the pattern of the second metal layer have an allowable error range of relative displacement. In the allowable error range of relative displacement, the overlapped area between the pattern layer of the drain electrode 406 and the scan line 404 is a constant. FIG. 4B is a top-view schematic diagram after the pattern of the second metal layer in FIG. 4A has displaced a distance X to the right relative to the pattern of the first metal layer. The reduced overlapped area A1 of the pattern layer of the drain electrode 406 and the scan line 404 is equal to the increased overlapped area A2, so as the overall overlapped area remains a constant.

Such as shown in FIG. 4A, the allowable error range of relative displacement not only exists in the left and right direction but also exists in the up and down direction, so there exists an allowable error range of relative displacement for any direction. In one preferred embodiment, the allowable error range of relative displacement is 0 to 5 micrometers. In the allowable error range of relative displacement, the overlapped are a between the pattern layer of the drain electrode 406 and the scan line 404 is a constant. Thus, the C_{gd} and the charge-discharge time of the pixel electrode are also constants. Consequently, the brightness and display quality of the whole display picture are even and fine.

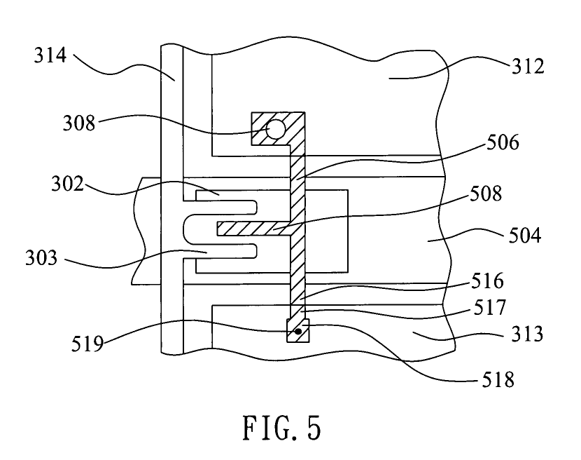

The third embodiment of the present invention is illustrated in the FIG. 5. Similar to the second embodiment, the pattern of the first metal layer and the pattern of the second metal layer also have an allowable error range of relative displacement. In the allowable error range of relative displacement, the overlapped area between the pattern layer of the drain electrode 506 and the scan line 504 is a constant. Different from the second embodiment, the scan line 504 has no protrusion and the gate electrode (not shown in the figure) is included in the line shape of the scan line 504. Similar to the second embodiment, the pattern layer of the source electrode 303 having a curved concavity is extended from the data line 314. The second extended portion 508 of the pattern layer of the drain electrode 506 is extended into the curved concavity of the pattern layer of the source electrode 303. Further, the pattern layer of the drain electrode 506 has the first extended portion 516. The first extended portion 516 is extended to the region between an adjacent pixel electrode 313 and the substrate. The first extended portion 516 partially overlaps with the pixel electrode 313 at the overlapped region 517 which has a square region 518.

Once the pixel is found to be a white defect, a laser beam is used to irradiate the region 519 to electrically connect the pattern layer of the drain electrode 506 with the adjacent pixel electrode 313. The region 519 is arbitrarily selected within the square region 518. Consequently, the current pixel will have the same brightness and color with the adjacent pixel, such that the repairing purpose is achieved.

The function of the square region 518 is to facilitate recognizing the repairing position, and its symmetric shape can assure the uniformity and strength of the laser fusion. Of course, a circle region or a symmetric polygon region can also provide the same function. This is one feature of the present embodiment.

To sum up, the present invention provides a simple active device array substrate and an easy repairing method thereof. To achieve the objects, the pattern layer of the drain electrode has an extended portion extending to the middle between an adjacent pixel electrode and the substrate. Once the pixel is found to be a white defect, a laser beam is used to irradiate the overlapped region of the extended portion of the pattern layer of the drain electrode and the adjacent pixel electrode. Then, the defect pixel mentioned above will have the same brightness and color with the adjacent pixel, such that the repairing purpose is achieved.

The foregoing descriptions of specific embodiments of the present invention have been presented for purposes of illustrations and description. They are not intended to be exclusive or to limit the invention to the precise forms disclosed, and obviously many modifications and variations are possible in light of the above teaching. The embodiments were chosen and described in order to best explain the principles of the invention and its practical application, to thereby enable others skilled in the art to best utilize the invention and various embodiments with various modifications as are suited to particular use contemplated. It is intended that the scope of the invention be defined by the Claims appended hereto and their equivalents.

What is claimed is:

1. An active device array substrate, comprising:
a substrate; and
a plurality of pixel structures configured in arrays on the substrate, wherein a plurality of scan lines and a plurality of data line are defined the pixel structures, each of the pixel structures comprises:
an active device configured on the substrate, wherein the active device comprises:
a pattern layer of a gate electrode configured on the substrate and electrically connecting with the corresponding scan line;
a gate insulation layer covering the pattern layer of the gate electrode and the substrate;
a channel layer configured on the gate insulation layer which is over the pattern layer of the gate electrode;
a pattern layer of a source electrode and a pattern layer of a drain electrode respectively configured on two sides of the channel layer, wherein the pattern layer of the source electrode is electrically connected with the corresponding data line, and the pattern layer of the drain electrode has a first extended portion; and
a passivation layer covering the active device; and
a pixel electrode configured on the passivation layer and electrically connecting with the pattern layer of the drain electrode, wherein the first extended portion of the pattern layer of the drain electrode is extended to the region between an adjacent pixel electrode and the substrate.

2. The active device array substrate according to claim 1, wherein the pattern layer of the source electrode is extended from the corresponding data line.

3. The active device array substrate according to claim 1, wherein the pattern layer of the gate electrode is extended from the corresponding scan line.

4. The active device array substrate according to claim 3, wherein the scan line further comprises a protrusion extended from the scan line and set besides the pattern layer of the gate electrode.

5. The active device array substrate according to claim 4, wherein the pattern layer of the drain electrode further comprises a second extended portion and a third extended portion, which the second extended portion extends to a upper side over the pattern layer of the gate electrode and the third extended portion extends to a upper side over the protrusion of the scan line.

6. The active device array substrate according to claim 5, wherein the pattern layer of the source electrode has a curved concavity and the second extended portion is extending into the curved concavity.

7. A repairing method of the active device array substrate according to claim 1, comprising:
providing the active device array substrate; and
electrically connecting the first extended portion of the pattern layer of the drain electrode with the adjacent pixel electrode.

8. The repairing method of the active device array substrate according to claim 7, wherein a laser fusion is used to electrically connect the first extended portion of the pattern layer of the drain electrode with the adjacent pixel electrode.
